(19) United States
(12) Patent Application Publication
(10) Pub. No.: US 2017/0352642 A1
(43) Pub. Date: Dec. 7, 2017

(54) APPARATUS FOR BONDING A SEMICONDUCTOR CHIP AND METHOD OF FORMING A SEMICONDUCTOR DEVICE

(71) Applicant: SK hynix Inc., Gyeonggi-do (KR)

(72) Inventor: Byung Chul KANG, Gyeonggi-do (KR)

(21) Appl. No.: 15/260,973

(22) Filed: Sep. 9, 2016

(30) Foreign Application Priority Data
Jun. 2, 2016 (KR) 10-2016-0068828

(51) Int. Cl. H01L 23/00

(52) U.S. Cl. CPC H01L 24/81; H01L 24/75; H01L 2224/81201; H01L 2224/75301; H01L 2224/81908; H01L 2224/7592

(57) ABSTRACT

An apparatus for bonding a semiconductor chip to a package substrate, the apparatus comprising: a die-bonding unit configured to attach the semiconductor chip to the package substrate; a load-measuring unit installed at the die-bonding unit, the load-measuring unit including a panel having a plurality of regions and a plurality of load-measuring members with at least one load-measuring member arranged in each of the regions of the panel to measure load values applied to each of the regions; and a controller configured to determine a load and a flatness of the semiconductor chip based on the load values measured by the load-measuring members.

### CROSS-REFERENCES TO RELATED APPLICATION

The present application claims priority under 35 U.S.C. §119(a) to Korean Patent Application number 10-2016-0068828, filed on Jun. 2, 2016. In the Korean Intellectual Property Office, the disclosure of which is incorporated herein by reference in its entirety.

### TECHNICAL FIELD

Various embodiments generally relate to an apparatus for manufacturing a semiconductor device and, more particularly, to an apparatus for bonding a semiconductor chip and a method of forming a semiconductor device.

### BACKGROUND

Generally, a semiconductor package may be manufactured by a process for singulating semiconductor chips from a wafer, a process for attaching the semiconductor chips to a package substrate, a process for molding the package substrate with the semiconductor chip, and a process for testing the package substrate with the semiconductor chip.

Typically, attaching a semiconductor chip to a package substrate, involves positioning the semiconductor chip on the package substrate using an adhesive and applying a pressure and a temperature to securely attach the semiconductor chip to the package substrate.

The attaching process may require predetermined recipes to improve a yield for manufacturing the semiconductor package.

### SUMMARY

According to an embodiment, there is provided an apparatus for bonding a semiconductor chip to a package substrate. The apparatus may include a die-bonding unit configured to attach the semiconductor chip to the package substrate; a load-measuring unit installed at the die-bonding unit, the load-measuring unit including a panel having a plurality of regions and a plurality of load-measuring members with at least one load-measuring member arranged in each of the regions of the panel to measure load values applied to each of the regions; and a controller configured to determine a load and a flatness of the semiconductor chip based on the load values measured by the load-measuring members.

In an embodiment, an apparatus for bonding a semiconductor chip, the apparatus comprising: a die-bonding unit attaching a chip on a package substrate; a load-measuring unit including a plurality of regions arranged in a plurality of rows and a plurality of columns disposed in the die-bonding unit; and a controller connected to the load-measuring unit and configured to determine a load and a flatness with respect to the chip, wherein each of the plurality of regions includes at least one load-measuring member.

In an embodiment, a method of forming a semiconductor device includes: attaching a chip on a package substrate in a die-bonding unit; sensing a signal from a load-measuring unit in the die-bonding unit, the load-measuring unit includes a plurality of regions arranged in a plurality of rows and a plurality of columns; and determining a load and a flatness with respect to the chip based on the signal by a controller connected to the load-measuring unit, wherein each of the plurality of regions includes at least one load-measuring member.

### BRIEF DESCRIPTION OF THE DRAWINGS

The above and other features and advantages of the present disclosure will become more apparent to those skilled in the art to which the present disclosure belongs by describing in detail various embodiments thereof with reference to the attached drawings in which:

FIG. 1 is a simplified block diagram illustrating an apparatus for bonding a semiconductor chip in accordance with an embodiment;

FIG. 2 is a plan view illustrating a die-bonding unit in accordance with an embodiment;

FIG. 3 is a plan view illustrating a load-measuring unit in accordance with an embodiment;

FIG. 4 is a simplified block diagram illustrating a controller in accordance with an embodiment; and

FIGS. 5 to 7 are cross-sectional views illustrating examples of the load-measuring unit in accordance with embodiments.

### DETAILED DESCRIPTION

Various embodiments will be described hereinafter with reference to the accompanying drawings. The embodiments may, however, be embodied in many different forms and should not be construed as limited to the examples of embodiments set forth herein. Rather, these examples of embodiments are provided so that this disclosure will be thorough and complete, and will fully convey the present disclosure to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Spatially relative terms, such as “under,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “under” other elements or features would then be oriented “above” the other elements or features. Thus, the example of the term “below” can encompass both an orientation of above and below. The device may be otherwise oriented (rotated 90 degrees or at other orientations) and the spatially relative descriptors used herein interpreted accordingly.

The terminology used herein is for the purpose of describing particular examples of embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs in view of the present disclosure. It will be further understood that terms, such as those defined in commonly used dictionaries, should be interpreted as having a meaning that is consistent with their meaning in the context of the present disclosure and the relevant art and will not be interpreted in an idealized or overly formal sense unless expressly so defined herein.

In the following description, numerous specific details are set forth in order to provide a thorough understanding of the present disclosure. The present disclosure may be practiced without some or all of these specific details. In other instances, well-known process structures and/or processes have not been described in detail in order not to unnecessarily obscure the present disclosure.

It is also noted, that in some instances, as would be apparent to those skilled in the relevant art, an element (also referred to as a feature) described in connection with one embodiment may be used singly or in combination with other elements of another embodiment, unless specifically indicated otherwise.

Hereinafter, examples of the embodiments will be explained with reference to the accompanying drawings.

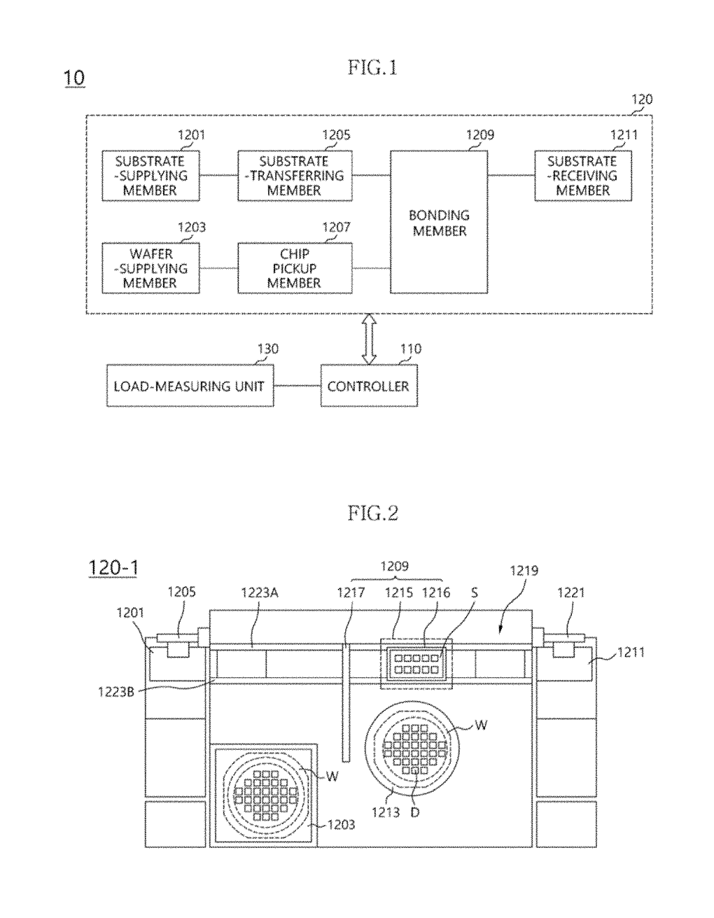

FIG. 1 is a simplified block diagram illustrating an apparatus 10 for bonding a semiconductor chip, in accordance with an embodiment.

Referring to FIG. 1, the apparatus 10 may include a controller 110, a die-bonding unit 120 and a load-measuring unit 130.

The controller 110 may be configured to control operations of the die-bonding apparatus 10. As illustrated in FIG. 1, the controller 110 may be positioned outside the die-bonding unit 120. In another embodiment, the controller 110 may be positioned in the die-bonding unit 120. In yet another embodiment, the controller 110 may be implemented using two controllers, one external to the die bonding unit 120 and one internal to the die bonding unit 120.

The die-bonding unit 120 may be configured to attach a semiconductor chip to a package substrate.

As illustrated in the embodiment of FIG. 1, the load-measuring unit 130 may be external to the die-bonding unit 120. In another embodiment (not illustrated), the load-measuring unit 130 may be arranged in the die-bonding unit 120. The load-measuring unit 130 may be configured to measure a load applied to the semiconductor chip and/or a flatness of the semiconductor chip in real time during operation of the die-bonding unit 120. The load-measuring unit 130 may measure the load applied to the semiconductor chip and/or the flatness of the semiconductor chip directly or indirectly.

In an embodiment, the load-measuring unit 130 may be provided to a unit for pressing the semiconductor chip to the package substrate, for example, a bonding head of the pressing unit. In another embodiment, the load-measuring unit 130 may be provided to a substrate stage of the die loading unit 120 (see element 1216 of FIG. 2). The substrate stage is configured to support the package substrate. The load-measuring unit 130 may be positioned near a bonding region of the die-bonding unit 120.

When the load-measuring unit 130 is provided to the bonding head or the substrate stage, the load-measuring unit 130 may directly measure the load and the flatness in real time when the semiconductor chip is attached to the package substrate. When the load-measuring unit 130 is positioned near the bonding region of the die-bonding unit 120, the load-measuring unit 130 may indirectly measure the load and the flatness with a time offset of a predetermined period from real time.

In an embodiment, the die-bonding unit 120 may include a substrate-supplying member 1201, a wafer-supplying member 1203, a substrate-transferring member 1205, a chip pickup member 1207, a bonding member 1209 and a substrate-receiving member 1211.

FIG. 2 is a plan view illustrating a die-bonding unit in accordance with an embodiment.

The substrate-supplying member 1201 may include a magazine configured to receive a plurality of the package substrates. The substrate-transferring member 1205 may be connected with a transferring mechanism 1219. The substrate-transferring member 1205 may be configured to transfer the package substrates in the substrate-supplying member 1201 to a die bonding region 1215.

The wafer-supplying member 1203 may include a cassette configured to receive a plurality of wafers W. The wafers W in the wafer-supplying member 1203 may be transferred to a wafer stage 1213 by a transferring arm (not shown).

The chip pickup member 1207 may be arranged under the wafer stage 1213. The chip pickup member 1207 may be configured to separate the semiconductor chips from the wafer W.

The bonding member 1209 may include a substrate stage 1216 and a bonding head 1217. The substrate stage 1216 may be configured to receive the package substrate S transferred by the substrate-transferring unit 1206 along rails 1223A and 1223B. The bonding head 1217 may be configured to transfer and attach the semiconductor chip D to the package substrate S.

The substrate-receiving member 1211 may include a magazine configured to receive the package substrate S with the semiconductor chip D. The package substrate S with the semiconductor chip D may be transferred to the substrate-receiving member 1211 by a substrate-transferring member 1221.

Hereinafter, operations for bonding the semiconductor chip by the die-bonding units 120 and 120-1 may be illustrated.

The package substrate S in the substrate-supplying member 1201 may be transferred to the substrate stage 1216 of the bonding region 1215 in the bonding member 1209 along the rails 1223A and 1223B by the substrate-transferring member 1205.

The wafer W in the wafer-supplying member 1203 may be transferred to the chip pickup member 1207. An accurate position at which the semiconductor chips D may be separated from the wafer W may be determined by a CCD camera and a vision algorithm. When the separation position is determined, the chip pickup member 1207 may separate the semiconductor chip D from the wafer W.

The bonding head 1217 of the bonding member 1209 may transfer the semiconductor chip D to the bonding region 1215. An accurate attaching position of the semiconductor chip D may be determined by a CCD camera and a vision algorithm. An adhesive may be coated on the package substrate S. Alternatively, an adhesive film may be attached to a rear surface of the semiconductor chip D. The bonding head 1217 may attach the semiconductor chip D to the package substrate S on the substrate stage 1216 using a pressure and a temperature. In an exemplary embodiment, a plurality of solder balls or a plurality of conductive bumps may be formed between the package substrate S and the semiconductor chip D.

The package substrate S with the semiconductor chip D may be transferred to the substrate-receiving member 1211. The package substrate S with the semiconductor chip D may be received in the substrate-receiving member 1211.

In an embodiment, the load-measuring unit 130 may be provided to the bonding head 1217, the substrate stage 1216, or combinations thereof. When the semiconductor chip D is attached to the package substrate D, the load-measuring unit 130 may measure the load and the flatness in real time.

In an embodiment, the load-measuring unit 130 may be positioned near the rails 1223A and 1223B in the bonding region 1215. The bonding head 1217 presses the load-measuring unit 130 for a time period and measures the load and the flatness for the period. The load-measuring unit 130 may be disposed on the bonding head 1217, the substrate stage 1216, the rails 1223A and 1223B, or combinations thereof.

In order to accurately measure the load and the flatness, the load-measuring unit 130 may be implemented with a plurality of load measuring members installed at a plurality of regions so that multiple measurements may be taken in real time. Hence, more than one load-measuring members may be provided to the plurality of regions, respectively.

When a pressure is applied to the load-measuring unit 130, the load-measuring members measure the loads by the regions. The measured loads by each of the load-measuring members in the various regions are transmitted to the controller 110.

The controller 110 may determine the loads by the regions based on the measured loads by the regions from the load-measuring members. The controller 110 may determine the flatness from the loads in the regions. Further, the controller 110 may obtain load changes in the regions based on the measured loads by the regions.

During the time the semiconductor chip D is being attached to the package substrate S, the controller 110 may obtain loads from the load-measuring members which are deployed in the various regions in real time. The controller 110 may calculate an average load, a maximum load and a minimum load based on the measured loads from the regions.

In an embodiment, the controller 110 may determine an average load for each region by averaging the measured loads for each region. The controller 110 may then determine the flatness based on the differences between the average loads of the regions. The controller 110 may obtain load changes for the regions using output signals from the load-measuring members deployed at the regions as a reference value under a no load condition.

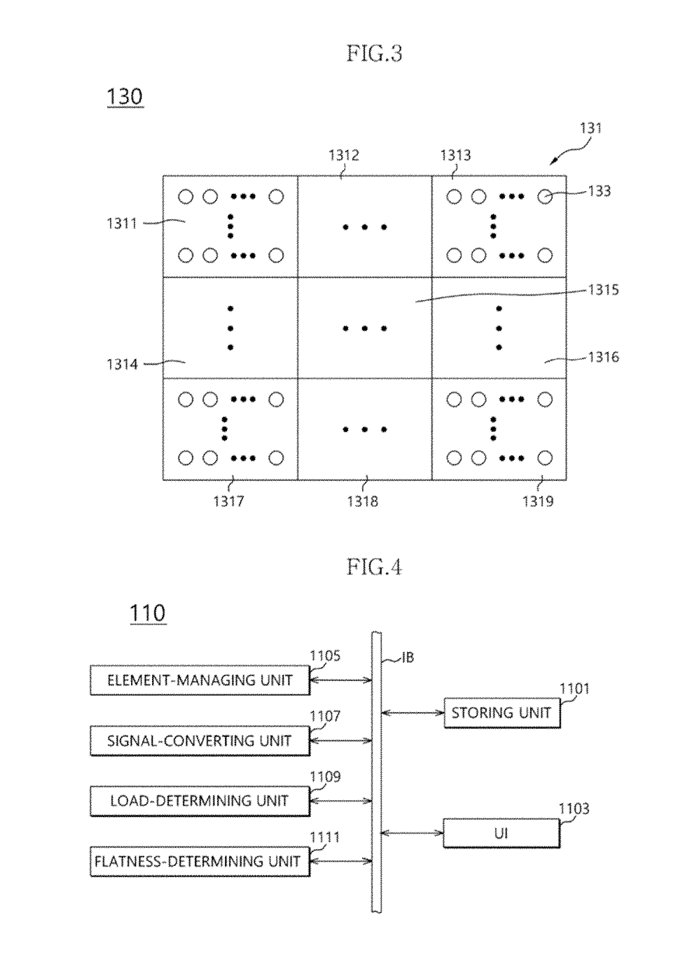

FIG. 3 is a plan view illustrating a load-measuring unit, in accordance with an embodiment.

Referring to FIG. 3, the load-measuring unit 130 may include a panel 131 and a plurality of load-measuring members 133. The panel 131 may have a plurality of regions 1311, 1312, 1313, 1314, 1315, 1316, 1317, 1318 and 1319. The load-measuring members 133 may be provided to the regions 1311, 1312, 1313, 1314, 1315, 1316, 1317, 1318 and 1319, respectively. In an embodiment, each of the plurality of regions 1311, 1312, 1313, 1314, 1315, 1316, 1317, 1318 and 1319 may include at least one load-measuring member 133.

The controller 110 may determine the load in each of the regions 1311, 1312, 1313, 1314, 1315, 1316, 1317, 1318 and 1319 based on the measured loads of the load-measuring members 133 in each of the regions 1311, 1312, 1313, 1314, 1315, 1316, 1317, 1318 and 1319.

The load-measuring members 133 may include various elements configured to output electrical signals corresponding to the measured loads.

Therefore, because the load-measuring unit 130 is divided into the regions 1311, 1312, 1313, 1314, 1315, 1316, 1317, 1318 and 1319 and the load-measuring members 133 are provided to the regions 1311, 1312, 1313, 1314, 1315, 1316, 1317, 1318 and 1319, respectively, the loads applied to the regions 1311, 1312, 1313, 1314, 1315, 1316, 1317, 1318 and 1319 may be accurately measured. Further, the flatness may be determined based on the load differences between the regions 1311, 1312, 1313, 1314, 1315, 1316, 1317, 1318 and 1319.

In an exemplary embodiment, the plurality of regions 1311, 1312, 1313, 1314, 1315, 1316, 1317, 1318 and 1319 may be arranged in a plurality of rows and a plurality of columns. The plurality of regions 1311, 1312, 1313, 1314, 1315, 1316, 1317, 1318 and 1319 may be arranged in 3 rows and 3 columns. A first region 1311 may be disposed on a first row and a first column. A fifth region 1315 may be disposed on a second row and a second column. A ninth region 1319 may be disposed on a third row and a third column. Each of the plurality of regions 1311, 1312, 1313, 1314, 1315, 1316, 1317, 1318 and 1319 may include one or more load-measuring members 133.

FIG. 4 is a simplified block diagram illustrating a controller, in accordance with an embodiment.

Referring to FIG. 4, the controller 110 may include a storing unit 1101, a user interface (UI) 1103, an element-managing unit 1105, a signal-converting unit 1107, a load-determining unit 1109 and a flatness-determining unit 1111.

The storing unit 1101 may include a main memory and an auxiliary memory. The storing unit 1101 may be configured to store operational programs for the apparatus 10, control data, application programs, operational parameters, processed results.

The user interface 1103 may include an Input interface and an output interface. The user may access to the apparatus 10 through the user interface 1103. The output interface may access the various parts of the controller via an internal bus IB.

The element-managing unit 1105 may be configured to manage identifiers of the load-measuring members 133 deployed in the regions 1311, 1312, 1313, 1314, 1315, 1316, 1317, 1318 and 1319 of the load-measuring unit 130. The element-managing unit 1105 may be configured to receive the measured loads of the load-measuring members 133. The load-measuring members 133 may output the measured loads under the no load condition and the load condition of the die bonding process. The load-measuring members 133 may transmit the outputted loads to the element-managing unit 1105. The identifiers of the load-measuring members 133 may include addresses or IDs of the load-measuring members 133 so that the element managing unit may identify the load-measuring member and/or the region of the load-measuring member for each received load.

The signal-converting unit 1107 may be configured to convert the loads provided from the load-measuring members 133 as electrical signals into load values. The signal-converting unit 1107 may store the load values provided from the element-managing unit 1105 under the no load condition as a reference value in the storing unit 1101.

The load-determining unit 1109 may be configured to determine the loads in each of the regions 1311, 1312, 1313, 1314, 1315, 1316, 1317, 1318 and 1319 in the die bonding process. The load-determining unit 1109 may be configured to receive the load values of the load-measuring members 133 provided from the signal-converting unit 1107. The load-determining unit 1109 may be configured to average the load values of the load-measuring members 133 for each of the regions 1311, 1312, 1313, 1314, 1315, 1316, 1317, 1318 and 1319 to calculate average load values for each of the regions 1311, 1312, 1313, 1314, 1315, 1316, 1317, 1318 and 1319.

The load-determining unit 1109 may calculate the load values in real time, the average values of the load values, a maximum load value and a minimum load value based on the load values by the regions 1311, 1312, 1313, 1314, 1315, 1316, 1317, 1318 and 1319 during the die bonding process.

The flatness-determining unit 1111 may be configured to determine the flatness based on the load values for each of the regions 1311, 1312, 1313, 1314, 1315, 1316, 1317, 1318 and 1319. The flatness-determining unit 1111 may calculate differences between the load values of the regions 1311, 1312, 1313, 1314, 1315, 1316, 1317, 1318 and 1319. The flatness-determining unit 1111 may determine the flatness based on the load differences.

The load values of the load-measuring members 133 may be provided through the element-managing unit 1105 and the signal-converting unit 1107 so that the load changes by the load-measuring members 133 may be recognized. The load changes may be displayed through the user interface 1103.

In an embodiment, the user interface 1103 may display visual data such as the load changes by the load-measuring members 133, the load values by the regions, the flatness, the load values in real time, the average load value, the maximum load value and the minimum load value. The visual data may be displayed in graphs, values, images, etc.

FIGS. 5 to 7 are cross-sectional views illustrating examples of the load-measuring unit, in accordance with an embodiment.

In FIG. 5, the load-measuring unit 130 may be installed at the bonding head 1217-1.

In an embodiment, the bonding head 1217-1 may include a transfer arm 201, a shank 203, an absorbing member 207 and the load-measuring unit 130.

The transfer arm 201 may be connected with the transferring mechanism 1219 of the die bonding unit 120. The transfer arm 201 may be moved in vertical and horizontal directions.

The shank 203 may be connected to the transfer arm 201. The shank 203 may be downwardly extended from the transfer arm 201. The shank 203 may have a vacuum hole 205 formed through a central portion of the shank 203 in a lengthwise direction of the shank 203. The shank 203 may include an inserting hole 211. The vacuum hole 205 may be extended to the inserting hole 211 through the central portion of the shank 203.

The load-measuring unit 130 may be arranged in the inserting hole 211. The absorbing member 207 may be combined with a lower end of the load-measuring unit 130. The absorbing member 207 may have a vacuum hole 209 configured to absorb the semiconductor chip D.

When the semiconductor chip D is pulled on the absorbing member 207 may then be pressed to the package substrate S. The load-measuring unit 130 may measure the load applied to the semiconductor chip D and the flatness of the absorbing member 207 in real time. The load-measuring unit 130 may have a structure and functions substantially the same as those of the load-measuring unit in FIG. 3.

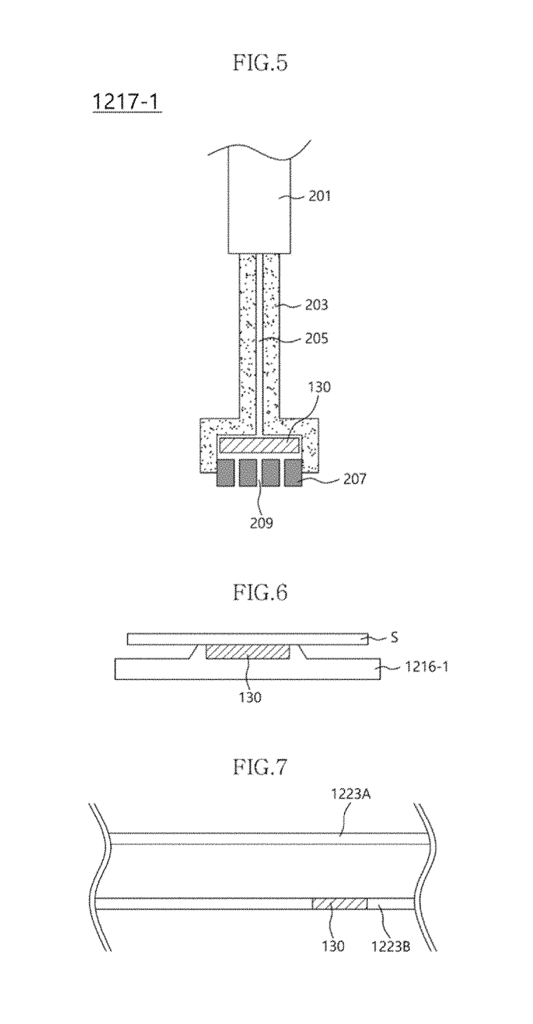

In FIG. 6, the load-measuring unit 130 may be installed at the substrate stage 1216.

In an embodiment, the load-measuring unit 130 may be combined with an upper portion of the substrate stage 1216-1. When the bonding head 1217 presses the semiconductor chip D to the package substrate S, the load-measuring unit 130 may measure the load applied to the semiconductor chip D and the flatness of the absorbing member 207 in real time. The load-measuring unit 130 may have a structure and functions substantially the same as those of the load-measuring unit in FIG. 3.

As shown in FIGS. 5 and 6, the load-measuring unit 130 may be installed at the bonding head 1217-1 or the substrate stage 1216-1. Alternatively, the load-measuring unit 130 may be installed at the bonding head 1217-1 and the substrate stage 1216-1.

In FIG. 7, the load-measuring unit 130 may be installed near the die bonding region 1215 of the bonding unit 120.

In an embodiment, the load-measuring unit 130 may be arranged over the rails 1223A and 1223B near the die bonding region 1215.

The bonding head 1217 may be periodically moved to the load-measuring unit 130 to uniformly press an upper end of the load-measuring unit 130. Thus, the load applied to a surface of the absorbing member 207 and the flatness of the absorbing member 207 may be measured. The period of the load measurement may be determined in accordance with the user. The load-measuring unit 130 may have a structure and functions substantially the same as those of the load-measuring unit in FIG. 3.

According to an embodiment, the load-measuring unit may be divided into regions. The load-measuring members may be positioned in the regions so that the load values for each of the regions may be calculated. The flatness may be determined based on the differences between the load values of the regions.

The load-measuring unit may be installed at the bonding head or the substrate stage of the die bonding apparatus to measure the load and the flatness simultaneously with the bonding process.

The bonding head may periodically press the load-measuring unit near a bonding region. The load and the flatness of the bonding head may be periodically measured.

The data such as the load changes by the regions, the load values by the regions, the flatness, the load values in real time, the average load value, the maximum load value, the minimum load value, etc., may be visually outputted so that the various states of the operation of the die bonding apparatus may be recognized in real time.

The above embodiments of the present disclosure are illustrative and are not intended to limit the present disclosure. Various alternatives and equivalents are possible. The examples of the embodiments are not limited by the embodiments described herein. Nor is the present disclosure limited to any specific type of semiconductor device. Other additions, subtractions, or modifications are obvious in view of the present disclosure and are intended to fall within the scope of the appended claims.

What is claimed is:

1. An apparatus for bonding a semiconductor chip to a package substrate, the apparatus comprising:
a die-bonding unit configured to attach the semiconductor chip to the package substrate;
a load-measuring unit installed at the die-bonding unit, the load-measuring unit including a panel having a plurality of regions and a plurality of load-measuring members with at least one load-measuring member arranged in each of the regions of the panel to measure load values applied to each of the regions; and
a controller configured to determine a load and a flatness of the semiconductor chip based on the load values measured by the load-measuring members.

2. The apparatus of claim 1, wherein the die-bonding unit comprises a bonding head configured to attach the semiconductor chip to the package substrate and the load-measuring unit is installed at the bonding head.

3. The apparatus of claim 1, wherein the die-bonding unit comprises a substrate stage configured to receive the package substrate and the load-measuring unit is installed at the substrate stage.

4. The apparatus of claim 1, wherein the die-bonding unit comprises a rail configured to transfer the package substrate and the load-measuring unit is installed at the rail.

5. The apparatus of claim 4, wherein the die-bonding unit further comprises a bonding head configured to attach the semiconductor chip to the package substrate and the bonding head periodically press the load-measuring unit by the controller.

6. The apparatus of claim 1, wherein the die-bonding unit comprises a bonding head configured to attach the semiconductor chip to the package substrate and a substrate stage configured to receive the package substrate and the load-measuring unit is installed at the bonding head and the substrate stage.

7. The apparatus of claim 1, wherein the controller comprises:
a signal-converting unit configured to convert the measured load values of the load-measuring members into load values; and
a load-determining unit configured to average the load values by the regions to calculate load differences by the regions.

8. The apparatus of claim 1, wherein the controller comprises:
a signal-converting unit configured to convert the measured load values of the load-measuring members into load values;
a load-determining unit configured to average the load values by the regions to calculate load differences by the regions; and
a flatness-determining unit configured to determine the flatness based on the load differences by the regions.

9. The apparatus of claim 1, wherein the controller is configured to obtain load changes by the load-measuring members based on a predetermined value and the measured load values of the load-measuring members.

10. The apparatus of claim 9, wherein the reference value comprises an output signal provided from the load-measuring members under no load condition.

11. The apparatus of claim 1, wherein the controller is configured to obtain load values by the regions by converting the measured load values of the load-measuring members into load values, the load values by the regions in real time, an average load value, a maximum load value and a minimum load value.

12. An apparatus for bonding a semiconductor chip, the apparatus comprising:
a die-bonding unit attaching a chip on a package substrate;
a load-measuring unit including a plurality of regions arranged in a plurality of rows and a plurality of columns disposed in the die-bonding unit; and
a controller connected to the load-measuring unit and configured to determine a load and a flatness with respect to the chip,
wherein each of the plurality of regions includes at least one load-measuring member.

13. The apparatus of claim 12, wherein the load-measuring unit is disposed on a bonding head, a stage, a rail in a bonding region, or combinations thereof.

14. The apparatus of claim 12, wherein the die-bonding unit comprises a bonding head including a shank and an absorbing member on the shank,
and wherein the load-measuring unit is disposed between the shank and the absorbing member.

15. A method of forming a semiconductor device, comprising:
attaching a chip on a package substrate in a die-bonding unit;
sensing a signal from a load-measuring unit in the die-bonding unit, the load-measuring unit includes a plurality of regions arranged in a plurality of rows and a plurality of columns; and
determining a load and a flatness with respect to the chip based on the signal by a controller connected to the load-measuring unit,
wherein each of the plurality of regions includes at least one load-measuring member.

16. The method of claim 15, wherein the load-measuring unit is formed on a bonding head, a stage, a rail in a bonding region, or combinations thereof.

17. The method of claim 15, wherein the die-bonding unit comprises a bonding head including a shank and an absorbing member on the shank,
and wherein the load-measuring unit is formed between the shank and the absorbing member.
